(19) United States
(12) Patent Application Publication
(10) Pub. No.: US 2026/0206267 A1
(43) Pub. Date: Jul. 16, 2026

(54) INSULATION PROCESS WITHIN A MICROELECTRONIC DEVICE

(71) Applicant: COMMISSARIAT A L'ENERGIE ATOMIQUE ET AUX ENERGIES ALTERNATIVES, Paris (FR)

(72) Inventors: Alice BOND, Grenoble Cedex 09 (FR); Tadeu MOTA FRUTUOSO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/425,048

(22) Filed: Dec. 18, 2025

(30) Foreign Application Priority Data
Dec. 19, 2024 (FR) FR2414599

(51) Int. Cl. H10D 62/10; H10D 86/00

(52) U.S. Cl. CPC H10D 62/115; H10D 86/201

(57) ABSTRACT

Aspects of the present disclosure provide a microelectronic device that includes an isolation zone between a first region and a second region of a semiconductor stack. The stack includes a semiconductor substrate, a buried oxide layer over the substrate, and a thin semiconductor layer over the buried oxide layer. The isolation structure extends through the thin semiconductor layer and the buried oxide layer to the semiconductor substrate and separates a first transistor from a second transistor. The isolation structure includes a spacer formed along sidewalls of the stack, an epitaxially grown semiconductor layer extending from the substrate, an insulating separating layer over the epitaxially grown semiconductor layer, and a conductive pattern over the separating layer configured to control current flow in the epitaxially grown semiconductor layer.

### TECHNICAL FIELD

The present invention relates to the field of microelectronic devices, in particular, transistors. It has, for example, a particularly advantageous application in the field of integrated circuits.

### PRIOR ART

The production of a set of microelectronic devices on one same wafer is accompanied by electrical isolation problems linked, on the one hand, to the appearance of parasitic diodes and, on the other hand, the isolation between devices.

The first main problem therefore relates to parasitic diodes appearing in certain device architectures. Indeed, it appears that when PMOS and NMOS are formed in respectively n and p doped wells, parasitic diodes appear at the junction between the wells of opposite dopings. These parasitic diodes are quite particularly inconvenient when they are formed at the junction between two wells with horizontally juxtaposed opposite dopings. Indeed, in this case, the polarisation range being able to be applied to the devices is highly reduced.

It is therefore necessary to achieve a shallow isolation to avoid these horizontal parasitic diodes. It could seem to be considered to achieve this isolation by a local oxidation method (commonly called LOCOS-Local Oxidation of Silicon). Yet, when a local oxidation is implemented, a lateral extension of the undesired oxidation, called “bird's beak” is systematically obtained, extending over at least twenty nanometres. This bird's beak creates a useless size: using a local oxidation technique therefore damages the density. In addition, a shallow isolation must be protected to avoid being fully consumed during the manufacturing method. It is therefore necessary to have a lateral small isolation, such that a gate of a typical width of 20 nm can protect it. The lateral extension systematically generated by a local oxidation method is therefore not compatible.

The second main problem relates to the electrical isolation between devices. Two main strategies exist today for the production of such an isolation.

A first method consists of making a polarised gate extend positively between two PMOS transistors (or a negatively polarised gate between two NMOS transistors), which has the effect of repelling the majority carriers on either side of the gate, and to isolate the two transistors. However, this technique is difficult to implement at regions of the wafer, where NMOS transistors and PMOS transistors are manufactured side by side. Indeed, the isolation of the NMOS and PMOS transistors requiring opposite polarisations of the gate, it is not possible to use a common gate to isolate the two types of transistors. Therefore, two distinct gates must be produced in the extension from one another and produce separate contacts, making it possible to polarise them differently, which encumbers the wafer and damages the density.

A second method consists of isolating the transistors by forming a deep trench (commonly called STI—Shallow Trench Isolation) to one another. However, due to the required depth and the current prior art, the STI cannot have a high aspect ratio, which loses the space on the wafer and also damages the density.

It can be considered to combine these two methods, for example, by isolating the PMOS transistors using a polarised gate positively and by isolating the NMOS transistors by an STI. In this solution, the polarised gate and the STI are located in the extension from one another. This track, however, would only have interest if the STI could have a width as low as the polarised gate. Yet, the gate typically has a width of 20 nm, a dimension which is not accessible for the STI through its depth and through the current techniques, in particular, filling techniques. Another way to perform this isolation is by local oxidation. However, as described above, a local oxidation leads to a bird's beak extending laterally over twenty nanometres. It is therefore impossible with the current methods to achieve an STI of a width comparable to the width of the polarised gate. The combination of the two methods is not therefore satisfactory, since it remains limited by the dimensional limits of the STI or local oxidation methods.

An aim of the present invention is therefore to resolve at least one of the problems presented above, and preferably to resolve the two simultaneously.

### SUMMARY

To achieve this objective, a first aim of the invention relates to a microelectronic device comprising an isolation between a first region and a second region, the device comprising a stack comprising, along a so-called stacking direction:
a. a substrate with the basis of a first semiconductor material, called semiconductor substrate,
b. a layer with the basis of an electrically isolating material, called buried oxide layer,
c. a layer with the basis of a second semiconductor material, preferably identical to the first semiconductor material, called thin layer.

The stack comprises a first region and a second region separated by an isolation zone extending between internal flanks of the stack, the isolation zone passing through the thin layer and the buried oxide layer and opening onto the semiconductor substrate.

The microelectronic device further comprising a first transistor and a second transistor, the first transistor and the second transistor being located respectively in the first and in the second region, the thin layer forming a first channel of the first transistor and a second channel of the second transistor.

The isolation zone advantageously comprises:
a. a spacer extending over the internal flanks of the stack, the spacer being with the basis of an electrically isolating material,
b. a layer with the basis of the first semiconductor material, called epitaxially grown layer, extending between the internal flanks of the stack and being in contact with the substrate,
c. a layer with the basis of an electrically isolating material, called separating layer, extending over the epitaxially grown layer, the separating layer fully covering the epitaxially grown layer,
d. an electrically conductive pattern extending over the separating layer.

The separating layer is in direct contact with the epitaxially grown layer, the electrically conductive pattern is in direct contact with the separating layer, the separating layer and the electrically conductive pattern being arranged to be able to enable, or not, a current flow in the epitaxially grown layer.

A second aim of the invention relates to a method for manufacturing an isolation zone between a first region and a second region of a microelectronic device, the method comprising the following steps:
a. providing a stack comprising at least, along a so-called stacking direction:
   i. a substrate with the basis of a first semiconductor material, called semiconductor substrate,
   ii. a layer with the basis of an electrically isolating material, called buried oxide layer,
   iii. a layer with the basis of a second semiconductor material, preferably identical to the first semiconductor material, called thin layer,
b. forming an opening in the stack, the opening passing through the thin layer and the buried oxide layer and opening onto the semiconductor substrate, the opening being defined by internal flanks of the stack, the opening separating the first region from the second region of the stack,
c. forming a spacer extending from the internal flanks of the stack, the spacer being with the basis of an electrically isolating material,
d. epitaxially growing, from the semiconductor substrate, a so-called epitaxially grown layer, at least partially filling the opening,
e. forming, on the epitaxially grown layer, a layer with the basis of an electrically isolating material called separating layer, the separating layer fully covering the epitaxially grown layer,
f. forming an electrically conductive pattern intended to form a gate pattern on the separating layer, the separating layer being in direct contact with the epitaxially grown layer, the electrically conductive pattern being in direct contact with the separating layer, the separating layer and the electrically conductive pattern being arranged to be able to enable, or not, a current flow in the epitaxially grown layer,
g. forming at least one first transistor in the first region and at least one second transistor in the second region, each transistor having a channel formed by the thin layer.

The manufacturing method, as well as the device according to the invention, have numerous advantages with respect to the prior art.

First, the method and the device according to the invention make it possible to achieve a double isolation:
a. A first isolation between the (N or P) doped well, in which the assembly is typically formed and the active regions of the devices, and this, through a small isolation zone. The present invention indeed makes it possible to achieve a small isolation. Yet, the fact that the isolation zone is small, makes it possible to be placed in an architecture, in which the P doped box is encompassed in the N doped box (box commonly called “deep N-well”) (or conversely). In this architecture, the N and P doped boxes are not juxtaposed in the plane of the substrate, but one on the other, along the vertical direction. This makes it possible to remove the horizontal parasitic diodes, the most damaging to the operation, and thus to resolve the first problem raised in the introduction.
b. A second isolation, thanks to the presence of the spacer between two devices formed at the first and second regions (typically two transistors), which resolves the second problem raised in the introduction.

The two problems are therefore resolved by manufacturing a spacer which, in the method according to the present invention, is cleverly achieved, in order to limit the complexity and the cost of the method.

Another advantage of the invention is that it is possible to resort to one single photolithography level to define isolation zones between two devices, in the middle of the active zone, and isolation zones separating devices and substrate engagement (bulk engagement), at the periphery of the active zone. The spacer used for the isolation at the periphery of the active zone moreover does not impact the operation of the hybrid zones, i.e. the zones where the buried oxide layer has been removed, typically present at the periphery of the substrate.

The method according to the invention moreover has the advantage of not requiring any chemical-mechanical polishing step, expensive method, damaging the yield and often altering the quality of the devices.

Generally, the method according to the invention, implement inexpensive steps (etching, oxidation).

Moreover, the method according to the invention does not resort to a local oxidation step, like certain methods of the prior art. This makes it possible to avoid the bird's beak phenomenon described in the introduction.

Furthermore, the dimensions of the spacer and of the epitaxially grown layer are defined, not by a local oxidation step, like in the prior art, but by an etching step, serving to define the opening in the stack. This enables a better control of these dimensions. Consequently, it is possible to reduce the margins taken to achieve the isolation between devices and therefore to increase the density of devices manufactured from one same stack.

Moreover, the isolation such as achieved according to the present invention can be achieved, before or after the formation of the active zones of the devices located on either side of the isolation zone. This makes the method more modulable.

The present invention thus makes it possible to simultaneously resolve the two problems raised in the introduction, and moreover has numerous advantages with respect to the prior art, making the solution easily integrable to the current manufacturing methods, and enabling both a better density, and a better manufacturing yield.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1N illustrate an embodiment of the method according to the invention.

FIGS. 2A to 2D are top views of different assemblies of transistors manufactured on one same wafer. These figures illustrate, in particular, different arrangements of the electrically conductive patterns connecting the transistors. FIG. 2E is a figure illustrating how the present invention can be integrated in hybrid zones to achieve the electrical isolation between devices and substrate engagement.

FIGS. 3A to 3D represent the value of the electrical field within different devices, including the device according to the present invention.

The drawings are given as examples and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to a preferred example, the separating layer extends from a first portion of the spacer covering a first internal flank of the stack up to a second portion of the spacer covering a second internal flank of the stack facing the first internal flank.

According to a preferred example, the spacer has a thickness e₂₀₀ measured along a direction perpendicular to the internal flanks of the stack, with e₂₀₀ greater than or equal to 4 nm and/or less than or equal 10 nm, preferably less than or equal to 6 nm.

According to a preferred embodiment, the spacer is buried in the stack, and preferably does not extend beyond an upper face of the thin layer opposite the buried oxide layer, for example, is flush with the upper face of the thin layer.

According to a preferred embodiment, the spacer passes through the thin layer and the buried oxide layer and, preferably, extends up to an upper face of the semiconductor substate located facing the buried oxide layer.

According to an example, the electrically conductive pattern has flanks covered by secondary spacers, the secondary spacers being directly in contact with the separating layer.

According to an example, the first region, the isolation zone and the second region are disposed along a first direction perpendicular to the stacking direction, in which the assembly formed by the electrically conductive pattern and the secondary spacers has a width E measured along the first direction, and in which the epitaxially grown layer has a width L₃₀₀ measured along the first direction, with E>L₃₀₀.

According to a preferred example, the separating layer has a thickness e₄₀₀, measured along the stacking direction, greater than or equal to 3 nm.

According to a preferred example, the epitaxially grown layer has a P-type or N-type doping.

According to a preferred embodiment of the method according to the second aim of the invention, coming from the epitaxial growth, the epitaxially grown layer extends, along the stacking direction, at least up to half the height of the buried oxide layer, preferably extends at least up to an upper face of the buried oxide layer opposite the substrate, preferably extends at least up to an upper face of the thin layer opposite the buried oxide layer, preferably exceeds the thin layer.

Another aim of the invention relates to a method for using the device according to the first aim of the invention, in which the pattern is electrically conductive, the method further comprising a step of polarising said pattern.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements.

By “selective etching with respect to”, or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA: B.

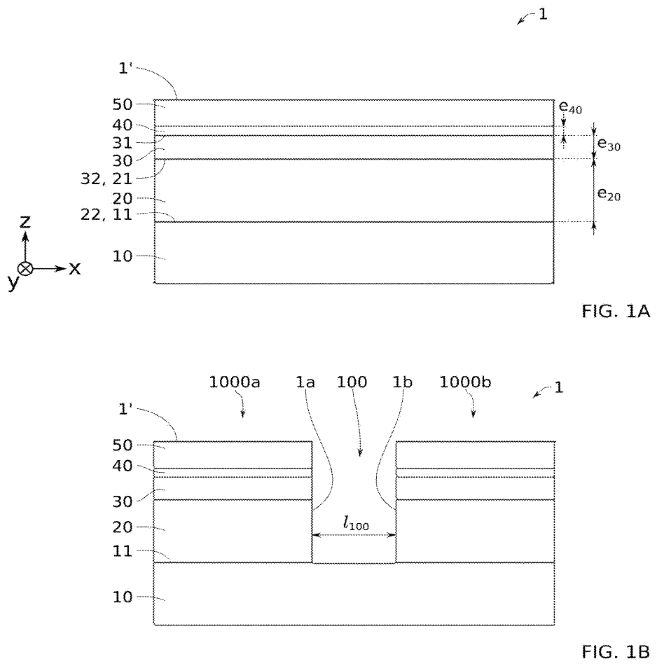

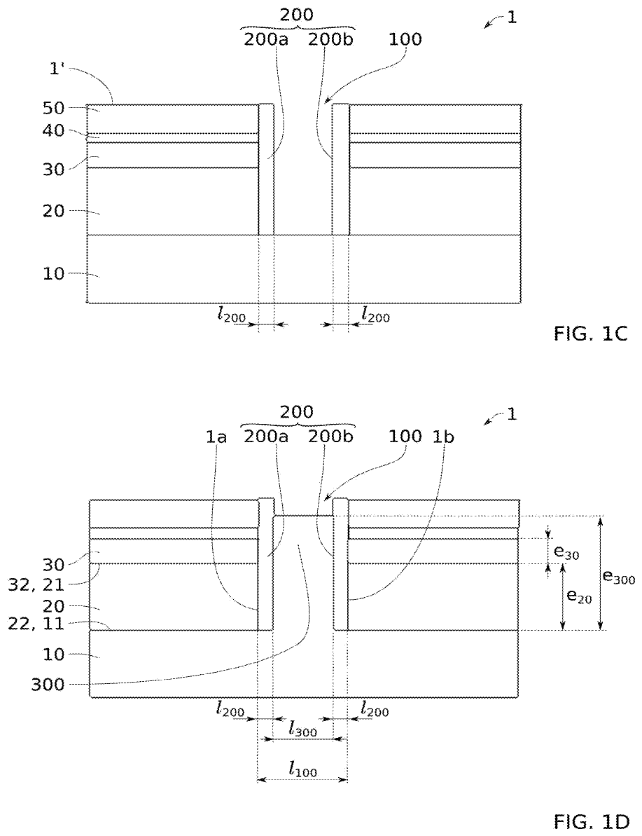

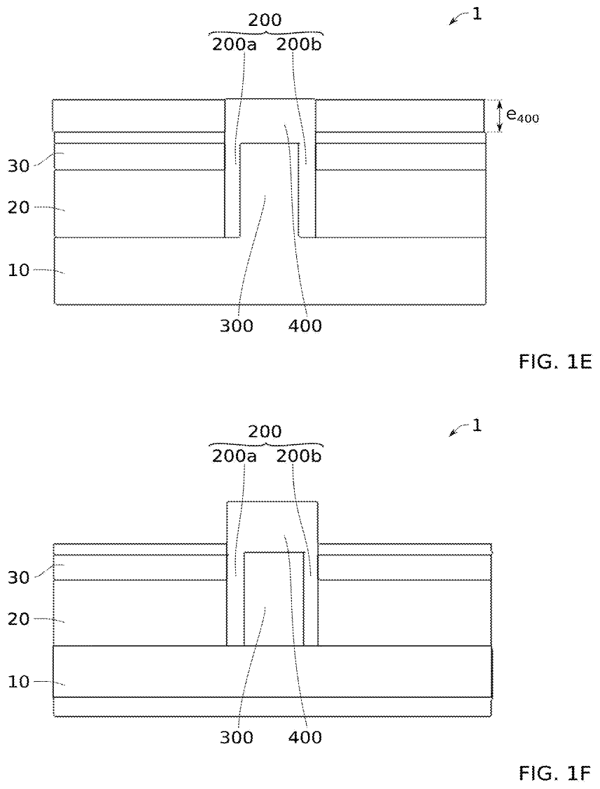

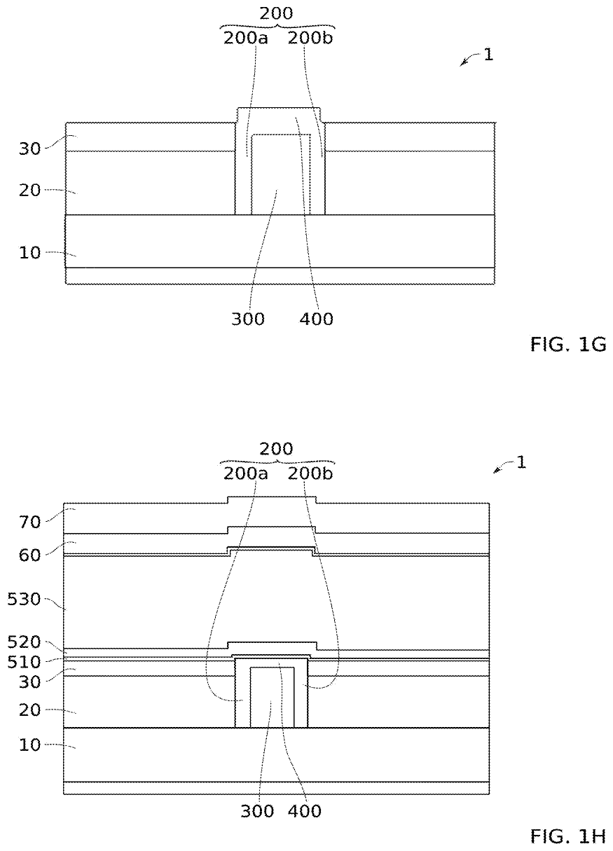

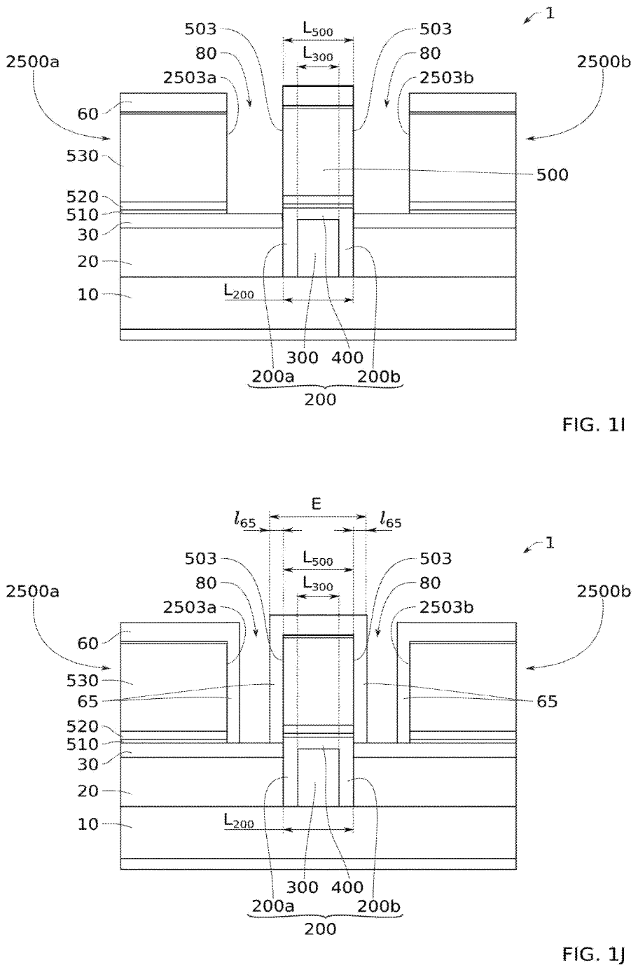

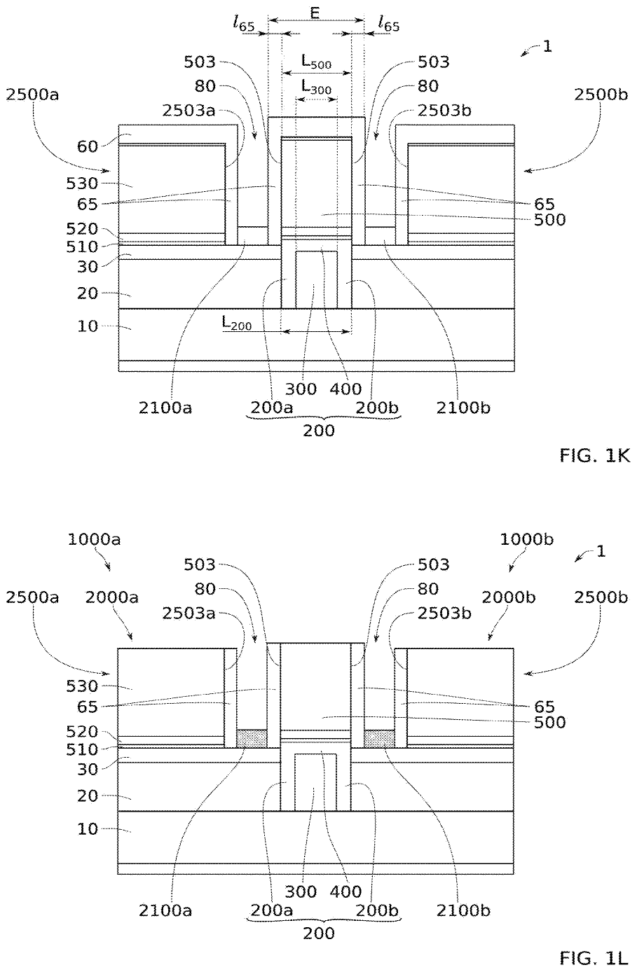

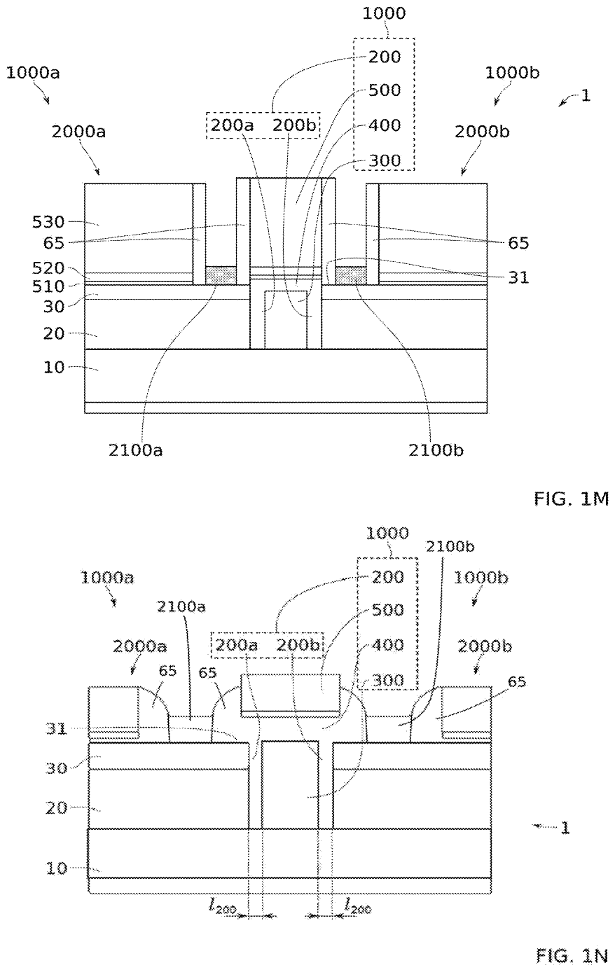

A preferably orthonormal system, comprising the axes X, Y, Z is represented in FIG. 1A. This system is applicable by extension to the other figures. The direction Z can be called “stacking direction”.

In the present patent application, thickness will preferably be referred to for a layer, and height will preferably be referred to for a structure or a device. The height is taken perpendicularly to the longitudinal plane XY. The thickness is taken along a direction normal to the main extension plane of the layer. Thus, a layer typically has a thickness along Z, when it extends mainly along the longitudinal plane XY, and a projecting element, for example, an isolation trench, has a height along Z. The relative terms “on”, “under”, “above”, “below”, “underlying” preferably refer to positions taken along the direction Z.

The terms “substantially”, “around”, “about” means “plus or minus 10%, preferably plus or minus 5%”.

An example of an embodiment of the method according to the invention will now be described in reference to FIGS. 1A to 1N.

FIG. 1A illustrates the provision of a stack 1. This stack comprises, stacked along the stacking direction Z: a semiconductor substrate 10, a buried oxide layer 20 and a thin layer 30. It can also comprise a dielectric layer 40 and/or a protective layer 50 surmounting the thin layer 30.

The substrate 10 is with the basis of a first semiconductor material, typically silicon. It has an upper face 11 mainly extending into a plane XY being able to be called transverse plane XY or longitudinal plane XY. This plane is defined by a first direction X and a second direction Y. The longitudinal plane and the stacking direction Z are typically perpendicular.

The buried oxide layer 20 is with the basis of an electrically isolating material, such as SIO₂. It has a thickness e₂₀ measured along the stacking direction Z. e₂₀ is, for example, greater than or equal to 10 nm and/or less than or equal to 145 nm, preferably greater than or equal to 20 nm and/or less than or equal to 30 nm. The buried oxide layer 20 has a lower face 22 facing the substrate 10 and an upper face 21, opposite its lower face 22 and opposite the substrate 10.

The thin layer 30 is with the basis of a second semiconductor material, for example, silicon. The thin layer 30 can also be called active layer 30. It has a thickness e₃₀ measured along the stacking direction Z. e₃₀ is, for example, greater than or equal to 3 nm and/or less than or equal to 80 nm, preferably greater than or equal to 5 nm and/or less than or equal to 15 nm. The thin layer 30 has a lower face 32 facing the substrate 10 and the buried oxide layer 20, and an upper face 31, opposite its lower face 32 and opposite the buried oxide layer 20.

The dielectric layer 40 is with the basis of an electrically isolating material such as SiO₂. It has a thickness e₄₀ measured along the stacking direction Z. e₄₀ is, for example, greater than or equal to 1 nm and/or less than or equal to 10 nm, preferably greater than or equal to 2 nm and/or less than or equal to 5 nm.

The protective layer 50 is, for example, SIN-based.

The stack 1 has an upper face 1′, corresponding, for example, in the figures, to the upper face of the protective layer 50. This mainly extends into the transverse plane XY.

As illustrated in FIG. 1B, the formation of an opening 100 in the stack 1 is then proceeded with. The opening 100 extends from the upper face 1′of the stack 1. It opens onto the substrate 1, for example, on its upper face 11. The opening 100 thus fully passes through the protective layer 50, the dielectric layer 40 (if the latter are present), the thin layer 30 and the buried oxide layer 20.

The opening 100 can be formed by conventional photolithography and etching steps, not illustrated.

Transversally, the opening 100 extends into the stack 1 between internal flanks 1a, 1b of the latter defined during the etching of the opening 100. The internal flanks comprise, in particular, a first internal flank 1a and a second internal flank 1b facing one another. The opening 100 has a width 1100 measured in the transverse plane XY, for example, in the figures along the first direction X. 1100 is typically greater than or equal to 5 nm and/or less than or equal to 100 nm, preferably greater than or equal to 10 nm and/or less than or equal to 20 nm.

The opening 100 separates two regions of the stack 1: a first region having the reference 1000a in FIG. 1B and a second region having the reference 1000b.

As illustrated in FIG. 1C, a spacer 200 is then formed in the opening 100, against the internal flanks 1a, 1b of the stack 1. The spacer 200 comprises, in particular, a first portion 200a extending from the first internal flank 1a of the stack and a second portion 200b extending from the second internal flank 1b of the stack 1.

The spacer 200 is with the basis of an electrically isolating material, such as SiO₂. It can be formed by an atomic layer deposition (ALD) method, which has the advantage of enabling the formation of a very conform layer.

The formation of the spacer 200 is typically followed by a directional etching to remove the horizontal portions of the deposited layer located at the bottom of the opening 100 (not represented) and strip the substrate 10, as well as the horizontal portions located on the layer 50 (not represented). Thus, the assembly illustrated in FIG. 1C is obtained.

The spacer 200 has a width I₂₀₀ measured in each of its portions 200a, 200b. I₂₀₀ is measured perpendicularly to the internal flanks 1a, 1b of the stack. I₂₀₀ is typically greater than or equal to 1 nm and/or less than or equal to 20 nm, preferably greater than or equal to 3 nm and/or less than or equal to 6 nm.

Then, a epitaxial growth step in the opening 100, from the substrate 10 is then proceeded with. This step makes it possible to form a semiconductor layer called epitaxially grown layer 300. The epitaxially grown layer 300 extends into the opening 100 from the first portion 200a of the spacer 200 covering the first internal flank 1a of the stack 1 up to the second portion 200b of the spacer 200 covering the second internal flank 2b of the stack 1.

The epitaxially grown layer 300 has a thickness e₃₀₀ measured along the stacking direction Z. e₃₀₀ is, for example, greater than or equal to 15 nm and/or less than or equal to 240 nm, preferably greater than or equal to 25 nm and/or less than or equal to 40 nm. Advantageously, the epitaxially grown layer 300 is typically raw, such that it extends at least as much as the thin layer 30 along the stacking direction Z, and preferably, that it extends beyond the thin layer 30 along the stacking direction Z, as illustrated in FIG. 1D. Thus, preferably, e₃₀₀≥e₂₀+e₃₀. In other words, the epitaxially grown layer 300 preferably passes through the buried oxide layer 20 and the thin layer 30. An interest of growing the epitaxially grown layer 300 beyond the thin layer 30 is to be able to form an oxide on this epitaxially grown layer (see the following step of forming a separating layer 400) selectively at the other surfaces in presence, for example, by thermal or plasma oxidation.

After the formation of the epitaxially grown layer 300, it is possible to proceed with the formation of a separating layer 400 above the epitaxially grown layer 300 (FIG. 1E). The separating layer 400 is with the basis of an electrically isolating material, for example, SiO₂. The separating layer 400 forms, with the first and the second portion of the spacer 200a, 200b, an electrically isolating unit. These elements isolate, in particular, electrically, the epitaxially grown layer of the thin layer 30. The formation of the separating layer 400 is typically accompanied by a partial oxidation of the epitaxially grown layer 300 from its upper face. This also explains the interest of growing the epitaxially grown layer 300 above the dimension along the direction Z that is desired to give it (see FIG. 1D), and in particular, beyond the thin layer 30: its thickness will be reduced, due to oxidation during the formation of the overlying separating layer 400.

The separating layer 400 has a thickness e₄₀₀ measured along the stacking direction Z. e₄₀₀ is, for example, greater than or equal to 2 nm and/or less than or equal to 10 nm, preferably less than or equal to 5 nm.

As illustrated in FIG. 1F, it is then possible to remove the protective layer 50. Also, preferably, the implantation of the semiconductor substrate 10 is proceeded with. Thus, a doped well is formed.

The dielectric layer 40 can then be removed (FIG. 1G), thus updating the thin layer 30, for example, for the formation of microelectronic devices.

The separating layer 400 can also be formed between the removal of the protective layer 50 (FIG. 1F) and the removal of the dielectric layer 40 (FIG. 1G), or also after the removal of the dielectric layer 40. The separating layer 400 can, for example, be formed during a subsequent step of forming a gate 500 on the epitaxially grown layer 300, between the epitaxially grown layer 300 and said gate 500.

From the assembly illustrated in FIG. 1G, two transistors are produced, on either side of the spacer 200. FIGS. 1H to 1N illustrate a preferred embodiment, in which the transistors 2000 and the electrically conductive pattern 500 are made at the same time.

As illustrated in FIG. 1H, an assembly of layers intended to form the gates of the transistors 2000a, 2000b and the electrically conductive pattern 500 is deposited on the stack 1. This assembly of layers comprises, for example:
A Gate Oxide 510,
A gate conductor 520,
A semiconductor layer 530, for example, polysilicon-based.

Advantageously, a protective layer 60 is deposited above the semiconductor layer 530, for example, made of nitride.

Moreover, an etching mask 70 is deposited on the protective layer 60. The assembly obtained is illustrated in FIG. 1H.

Then, an etching is done through the etching mask 70 to form, in the stack, two secondary openings 80 each opening on the epitaxially grown layer 300. These two secondary openings 80 delimit the gates 2500a, 2500b of the transistors 2000a, 2000b of the electrically conductive pattern 500.

Following the etching, the etching mask 70 is preferably removed. The assembly illustrated in FIG. 11 is obtained. By construction, the etching defines the width L₅₀₀ of the electrically conductive pattern 500 in the transverse plane XY. L₅₀₀ is less than or equal to L₂₀₀, the dimension between the external flanks of the portions 200a, 200b of the spacer 200. This makes it possible to avoid any contact between the electrically conductive pattern 500 and the thin semiconductor layer 30. Advantageously, L₅₀₀ is greater than L₃₀₀, the width of the epitaxially grown layer 300.

L₅₀₀ and L₃₀₀ are the dimensions respectively of the electrically conductive pattern 500 and of the epitaxially grown layer 300 in the transverse plane XY, along the direction in which the transistors 2000a, 2000b are aligned (in this case, X). L₂₀₀ is also measured along the direction in which the transistors 2000a, 2000b are aligned. It is measured from the flank of the first portion 200a of the spacer 200 extending against the buried oxide layer 20 up to the flank of the second portion 200b of the spacer 200 extending against the buried oxide layer 20. L₂₀₀ is thus typically equal to 1100, the width of the opening 100.

Then, secondary spacers 65 are formed in the secondary openings 80, against the flanks 503 of the electrically conductive pattern 500 and against the flanks 2503a, 2503b of the gates 2500a, 2500b of the transistors 2000a, 2000b. The secondary spacers 65 are with the basis of an electrically isolating material, typically nitride-based. It is understood that only half of each gate 2500a, 2500b is represented, and that therefore one single flank is represented for each gate, but that during this step, secondary spacers 65 are advantageously formed against all the flanks of the gates 2500a, 2500b.

The secondary spacers 65 have a width 165 measured perpendicularly to the flanks 2503a, 2503b of the gates 2500a, 2500b of the transistors 2000a, 2000b and to the flanks 503 of the electrically conductive pattern 500.

The width of the assembly formed by the secondary spacers 65 and the electrically conductive pattern 500 is referenced E (see FIG. 1J). The width E is equal to 2*I₆₅+L₅₀₀. The width E is greater than L₃₀₀. Preferably, E is greater than L₂₀₀. This makes it possible to avoid any stripping of the epitaxially grown layer 300 during subsequent steps, protecting it from the subsequent epitaxy resumption step.

An epitaxy resumption is then performed in the secondary openings 80 from the thin layer 30. This epitaxial growth enables the formation of drains and sources 2100a, 2100b of the transistors 2000a, 2000b (FIG. 1K). It must be noted that only any one from among the drain and the source is illustrated in the figures for each transistor. It is understood that this step enables the formation of both the drain and the source of each transistor 2000a, 2000b.

During this step, the secondary spacers 65 serve to avoid an epitaxial resumption occurring from the semiconductor layer 530.

Then, the protective layer 60 is removed at the apex of the gates 2500a, 2500b, preferably selectively. For example, this removal can be done by producing new oxide spacers (not represented) to protect the nitride secondary spacers 65.

Moreover, the sources and drains 2100a, 2100b of the transistors 2000a, 2000b are doped through secondary openings 80 (see the zones in a dotted line representing the doping in FIG. 1L).

Thus, the assembly illustrated in FIG. 1M is obtained, where the first transistor 2000a is located in the first region 1000a and the second transistor is located in the second region 2000a of the stack 1. These two transistors 2000a, 2000b are electrically isolated from one another, thanks to the presence of the spacer 200. Another geometry, which can also be considered, is illustrated in FIG. 1N. In FIG. 1N, the two transistors 2000a, 2000b and the isolation zone 1000 are found, and more generally, all the elements illustrated in FIG. 1M.

In the microelectronic device obtained, the gate pattern 500 and the separating layer 400 are configured to be able to enable, or not, the current flow in the epitaxially grown layer 300. The gate pattern 500 and the separating layer 400 thus have a role of controlling the passage of the current in the epitaxially grown layer 300.

Moreover, in the microelectronic device obtained, no semiconductor material zone is located above the isolation zone 1000. The isolation zone 1000 is only covered by the electrically conductive pattern 500 (or gate pattern 500), and optionally the secondary spacers 65 made of isolating material. This enables an optimal isolation between the transistors 2000a, 2000 b, and this, thanks to a narrow isolation zone 1000 (less than 100 nm even 50 nm and even 20 nm) enabling a densification of the transistors. The production of the electrically conductive pattern 500 with the same method as the gates of the transistors 2000a, 2000b makes it possible to achieve this isolation with very few modifications with respect to a standard production method. The electrically conductive pattern 500 is thus located substantially at the same level as the gates of the transistors 2000a, 2000b.

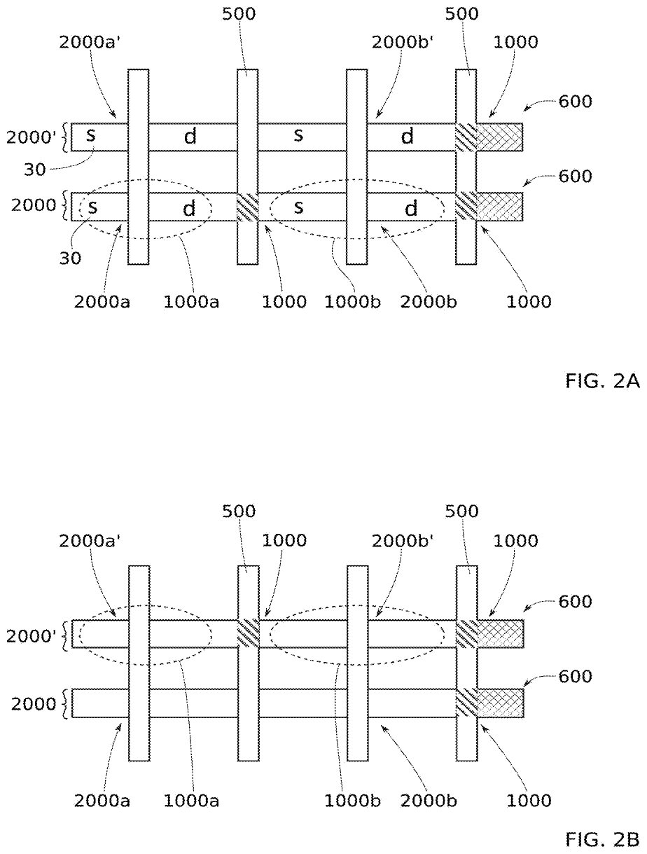

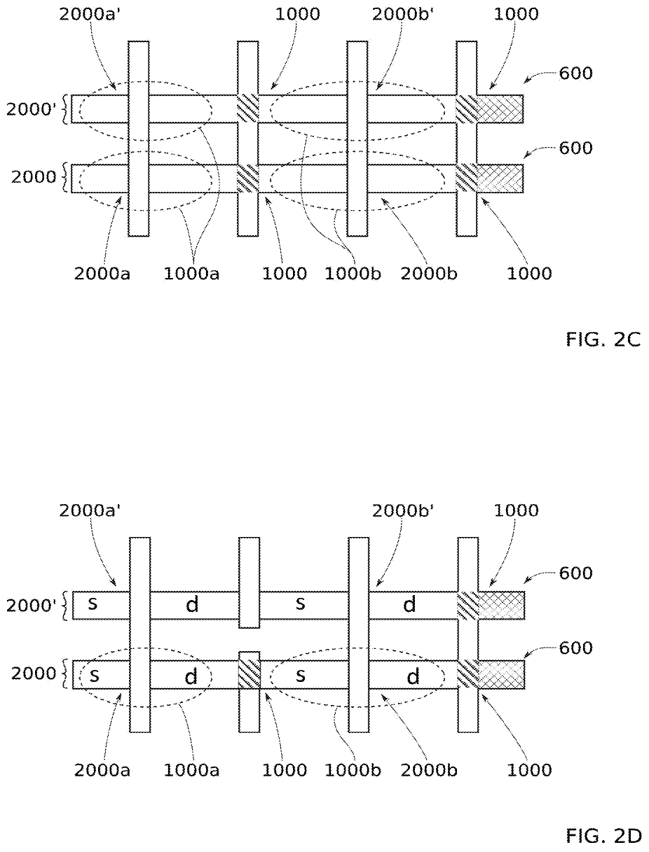

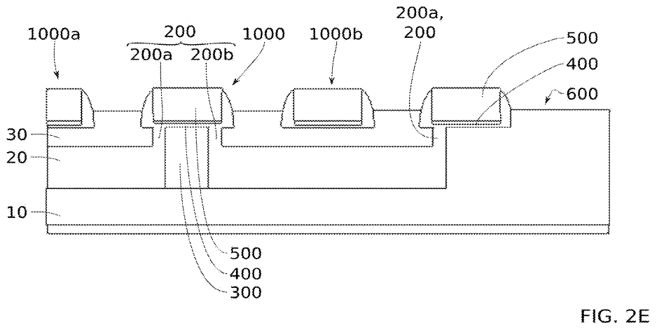

FIGS. 2A to 2D are top views of several assemblies of transistors manufactured by one same wafer. These views are given as possible integration examples of the present invention. The reference 2000 points to rows of NMOS-type transistors, and the reference 2000′ to rows of PMOS-type transistors. The transistors are represented very schematically, so as to enable, above all, the understanding of their location. The reference 1000 points to the isolation zone according to the present invention (hatched zone in the figure). Such that this zone can be seen, the electrically conductive pattern 500 has not been illustrated at this zone, but it is understood that it is actually present.

A first example of integration of the invention is illustrated in FIG. 2A. As illustrated, the electrically conductive pattern 500 extends above the region of the wafer, where the PMOS transistors are disposed. More specifically, it extends between a first PMOS transistor 2000a′ and a second PMOS transistor 2000b′. By polarising this electrically conductive pattern 500 positively, these two neighbouring PMOS transistors 2000a′, 2000b′ come to be electrically isolated. For reasons of simplification of the manufacturing methods, of rationalising costs and saving space, it is advantageous that the electrically conductive pattern 500 is extended above the region where the NMOS transistors are disposed. The positive polarisation of the electrically conductive pattern 500 however does not enable the isolation of the neighbouring NMOS transistors 2000a, 2000b. The isolation zone 1000 according to the present invention can thus be integrated between the two neighbouring NMOS transistors 2000a, 2000b, in order to electrically isolate them. The electrically conductive pattern 500 can thus be common to the PMOS and NMOS transistor zones.

A second example of integration is illustrated in FIG. 2B. In this example, the electrically conductive pattern 500 is polarised negatively, so as to isolate the two neighbouring NMOS transistors 2000a, 2000b. The isolation zone 1000 according to the present invention is integrated between the two neighbouring PMOS transistors 2000a′, 2000b′.

According to a third example of integration illustrated in FIG. 2C, an isolation zone 1000 according to the present invention is integrated both between the two neighbouring NMOS transistors 2000a, 2000b and between the two neighbouring PMOS transistors 2000a′, 2000b′.

According to a fourth example of integration illustrated in FIG. 2D, the isolation zone 1000 according to the present invention is integrated between the two neighbouring NMOS transistors 2000a, 2000b (or between the two neighbouring PMOS transistors 2000a′, 2000b′) and the electrically conductive pattern 500 is discontinuous, and in particular has a discontinuity between the isolation zone 1000 separating the NMOS transistors 2000a, 2000b and the portion of the pattern 500 separating the PMOS transistors 2000a′, 2000b′.

FIG. 2E illustrates the way in which the present invention can be integrated at the active end of line. As illustrated, to separate a region 1000b from a substrate engagement 600 (bulk engagement) located at the wafer border (criss-crossed zones in FIGS. 2A to 2D), it is possible to form a spacer 200a separating the region 1000b from the substrate 10 and to dispose above the substrate 10, a separating layer 400 and an electrically conductive pattern 500, like in the other isolating zones 1000. This isolation zone can be manufactured at the same time as the isolation zones separating two devices. It is, in particular, possible to form the spacer 200a at the same time as those of the other isolation zones, and to perform an epitaxy from the substrate 10 at the same time as the formation of the epitaxially grown layer 300 of the other isolation zones. The separating zones 400 and the patterns 500 can also be formed simultaneously. The present invention therefore makes it possible to simultaneously produce all the necessary isolation zones on a substrate.

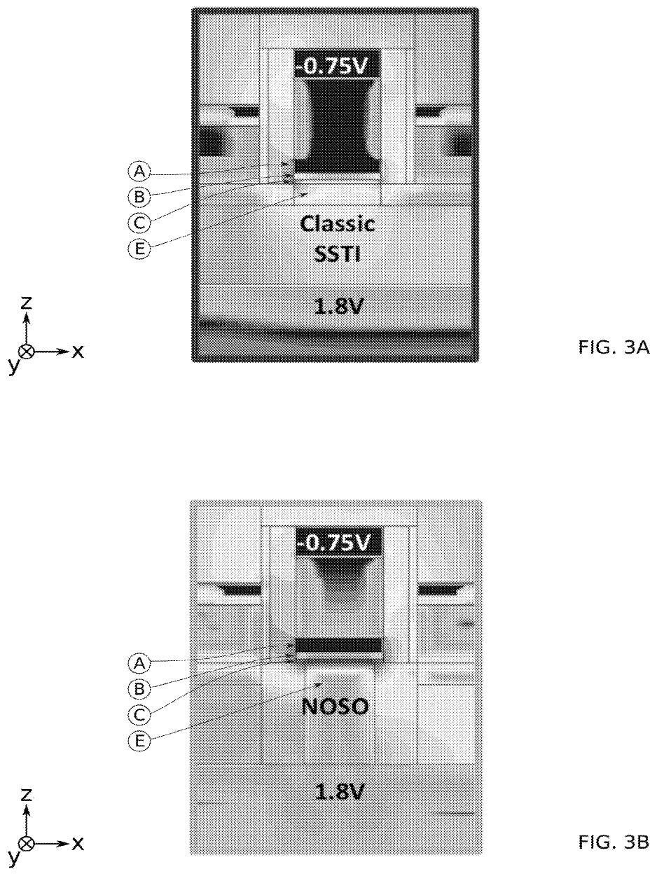

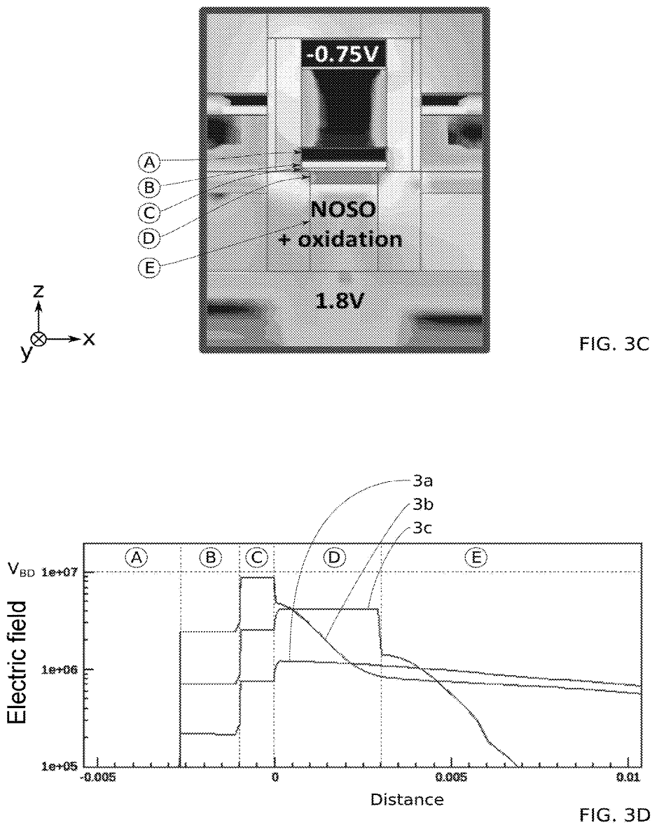

FIGS. 3A to 3D are results of simulations showing the interest of the present invention.

FIGS. 3A to 3C illustrate the distribution of the electric field within different transistor structures: FIG. 3A corresponds to a structure of the prior art with conventional STI isolation, FIG. 3B corresponds to a structure having an isolation with epitaxially grown layer underlying the transistor, while FIG. 3C corresponds to a structure integrating the assembly according to the present invention, with, in particular, an underlying epitaxially grown layer 300 and a separating layer 400.

FIG. 3D is a graph showing the development of the electric field as a function of the depth along the direction Z in the device. Different zones are referenced both in FIGS. 3A to 3C and in FIG. 3D for a better understanding of the figures:
a. Zone “A”: corresponds to the gate of the transistor,
b. Zone “B”: corresponds to a dielectric layer (typically HfO₂),
c. Zone “C”: corresponds to an oxide interlayer, for example, made of SiO₂,
d. Zone “D”: only present in FIG. 3C relating to an assembly according to the present invention, it corresponds to the separating layer 400,
e. Zone “E”: corresponds to the epitaxially grown layer 300.

The curves 3a, 3b and 3c of FIG. 3D correspond to the electric field in each of the structures of the FIGS. 3A, 3B and 3C as a function of the depth in the device.

It is observed that in the case of the structure 3B, the value of the electric field is very close to the value corresponding to the breakdown voltage of the device. The greatest electric field values are taken at the interlayer (see zone B in FIG. 3B). In operation, the value of the voltage in certain zones of the transistor, is therefore close to critical voltage values, being able to be synonymous with alteration, even destruction of the device.

It is observed, in comparison, that the voltage in the structure implementing the present invention and illustrated in FIG. 3C does not rise to as high values. In particular, the electric field within the interlayer is around three times greater than in the same layer within the structure of FIG. 3B.

It is moreover observed that the electric field in the epitaxially grown layer of the structure of FIG. 3C is lower than in the other structures. This, in particular, conveys the reduction of the parasitic capacities under the transistor.

Through the different embodiments described above, it appears that the present invention proposes an effective solution to achieve the isolation of two regions intended to serve as a basis for manufacturing microelectronic devices such as transistors. The invention effectively resolves the problem of lateral isolation between devices, and that of parasitic diodes, typically appearing in the structures of the prior art.

The invention is not limited to the embodiments described above, and extends to all the embodiments covered by the invention.

1-12. (canceled)

13. A microelectronic device comprising an isolation zone between a first region and a second region, the device comprising a stack extending along a stacking direction and including:
a semiconductor substrate comprising a first semiconductor material;
a buried oxide layer over the semiconductor substrate and comprising an electrically insulating material; and
a thin semiconductor layer over the buried oxide layer and comprising a second semiconductor material,
wherein the stack comprises the first region and the second region separated by the isolation zone extending between internal flanks of the stack, the isolation zone passing through the thin semiconductor layer and the buried oxide layer and opening onto the semiconductor substrate,
wherein the microelectronic device further comprises a first transistor and a second transistor located respectively in the first region and the second region, the thin semiconductor layer forming a first channel of the first transistor and a second channel of the second transistor,
wherein the isolation zone comprises:
a spacer extending along the internal flanks of the stack, the spacer comprising an electrically insulating material;
an epitaxially grown layer comprising the first semiconductor material and extending between the internal flanks of the stack and in contact with the semiconductor substrate;
a separating layer comprising an electrically insulating material and extending over the epitaxially grown layer, the separating layer fully covering the epitaxially grown layer; and
an electrically conductive pattern extending over the separating layer,
wherein the separating layer is in direct contact with the epitaxially grown layer, the electrically conductive pattern is in direct contact with the separating layer, and the separating layer and the electrically conductive pattern are configured to enable or prevent current flow in the epitaxially grown layer.

14. The device of claim 13, wherein the separating layer extends from a first portion of the spacer covering a first internal flank of the stack to a second portion of the spacer covering a second internal flank of the stack facing the first internal flank.

15. The device of claim 13, wherein the spacer has a thickness measured along a direction perpendicular to the internal flanks of the stack that is greater than or equal to 4 nm and less than or equal to 10 nm.

16. The device of claim 13, wherein the spacer is buried in the stack and does not extend beyond an upper surface of the thin semiconductor layer opposite the buried oxide layer.

17. The device of claim 13, wherein the spacer passes through the thin semiconductor layer and the buried oxide layer and extends to an upper surface of the semiconductor substrate facing the buried oxide layer.

18. The device of claim 13, wherein the electrically conductive pattern includes flanks covered by secondary spacers, the secondary spacers being in direct contact with the separating layer.

19. The device of claim 18, wherein the first region, the isolation zone, and the second region are disposed along a first direction perpendicular to the stacking direction,
wherein an assembly formed by the electrically conductive pattern and the secondary spacers has a width measured along the first direction,
wherein the epitaxially grown layer has a width measured along the first direction, and
wherein the width of the assembly is greater than the width of the epitaxially grown layer.

20. The device of claim 13, wherein the separating layer has a thickness measured along the stacking direction that is greater than or equal to 3 nm.

21. The device of claim 13, wherein the epitaxially grown layer has a P-type or N-type doping.

22. A method for using the device of claim 13, comprising electrically polarizing the electrically conductive pattern.

23. A method of manufacturing a microelectronic device including an isolation zone between a first region and a second region, the method comprising:
providing a stack extending along a stacking direction, the stack including:
a semiconductor substrate comprising a first semiconductor material;
a buried oxide layer comprising an electrically insulating material; and
a thin semiconductor layer comprising a second semiconductor material;
forming an opening in the stack that passes through the thin semiconductor layer and the buried oxide layer and opens onto the semiconductor substrate, the opening separating the first region from the second region of the stack;
forming a spacer extending from internal flanks of the stack within the opening, the spacer comprising an electrically insulating material;
epitaxially growing, from the semiconductor substrate, an epitaxially grown layer at least partially filling the opening;
forming a separating layer comprising an electrically insulating material on the epitaxially grown layer so as to fully cover the epitaxially grown layer;
forming an electrically conductive pattern on the separating layer; and
forming at least one first transistor in the first region and at least one second transistor in the second region, each transistor having a channel formed by the thin semiconductor layer.

24. The method of claim 23, wherein the epitaxially grown layer extends, along the stacking direction, at least up to half a height of the buried oxide layer.
